(19) United States
(12) Patent Application Publication
(10) Pub. No.: US 2009/0155492 A1
(43) Pub. Date: Jun. 18, 2009

(54) METHOD AND APPARATUS FOR COATING GLASS

(75) Inventors: Markku Rajala, Vantaa (FI); Anssi Hovinen, Espoo (FI); Kai Asikkala, Helsinki (FI)

Correspondence Address: OLIFF & BERRIDGE, PLC, P.O. BOX 320850, ALEXANDRIA, VA, 22320-4850, US

(73) Assignee: BENEQ OY, Vantaa (FI)

(21) Appl. No.: 12/296,284

(22) PCT Filed: Apr. 18, 2007
(86) PCT No.: PCT/FI2007/050200

§ 371 Date: Oct. 7, 2008

(30) Foreign Application Priority Data
Apr. 19, 2006 (FI) 20060373

(51) Int. Cl. C23C 16/44; C03C 17/245; C03C 17/02

(52) U.S. Cl. 427/585; 118/715

(57) ABSTRACT

A method and apparatus for coating glass with a CVD method, the coating being deposited by delivering some of the coating material into coating in the form of solid particles, whose composition is substantially the same as the composition of the coating to be deposited and whose diameter is less than 200 nm.

### FIELD OF THE INVENTION

The present invention relates to a method according to the preamble of claim 1 for coating glass by means of a CVD method. The invention particularly relates to the coating of glass at a temperature of 450-750° C. Further, the invention relates to an apparatus according to the preamble of claim 6 for coating glass. According to the invention, glass may be coated in connection with the manufacture or processing, such as hardening, of flat glass at the production rate. According to the invention, this is achieved by delivering at least some of the coating in the form of small particles onto the glass surface, whereby the reaction speed of substances used in the coating process does not form a factor limiting the coating speed. The coating on the glass may be a ‘low-e’ coating that reflects infrared radiation or a self-cleaning coating, for example. Moreover, the coating may consist of modifying the glass surface in such a way that the coating agents at least partly dissolve and diffuse into the glass matrix and thereby change the structure of the surface layer of the glass.

### DESCRIPTION OF THE PRIOR ART

Most often the glass used in buildings and cars is coated. The coating may be applied to change the transmittance of electromagnetic radiation through the glass, which allows the ultraviolet, infrared or visible light penetrating into and out of houses and cars to be regulated. The coating may also be used for providing the glass surface with self-cleaning or hydrophobic properties.

Coating is also often used on packing glass. The coating may be used for filtering ultraviolet light, for example, whereby the contents of the packaging is not damaged due to uv-light.

Coatings are typically produced using chemical vapour deposition (CVD), spray pyrolysis or sputtering. Of these methods, CVD and spray pyrolysis enable to produce hard coatings that have a significantly better resistance than sputtered coatings. Hard coatings are also referred to as pyrolytic coatings, and they are produced in a process where the temperature of the glass exceeds 400° C.

In the following the prior art is described mainly using low-e coatings as an example, because their commercial significance is the greatest.

U.S. Pat. No. 2,564,708 discloses a coating produced on the surface of glass to reflect infrared radiation. The invention disclosed in the patent is based on an observation according to which thin films of specific metal oxides on glass surface reflect electromagnetic radiation having a wavelength greater than 2 μm. Metals that formed effective oxides or mixtures of oxides were cadmium, indium, tin and antimony. Best results were obtained by combining tin and antimony oxides. In the best film the starting material consisted of 100 g of SnCl₄.5H₂O, 4 g of SbCl₃, 1 g of ZnCl₃, 50 cc of H₂O and 10 cc of HCl, which results in an oxide composition with 93.2% of SnO₂, 2.7% of Sb₂O₃. The aqueous solution was sprayed onto a glass plate having a temperature of more than 500° C. The oxide coating thus formed adhered firmly to the glass. The coating had a thickness of 100-700 nm. During the coating the temperature of the glass was 700° C., and it took 10 to 20 seconds to obtain a film of a desired thickness.

U.S. Pat. No. 3,473,944 discloses a sun-protection glass. The invention is based on an observation according to which a coating of tin oxide doped with antimony and applied to both sides of the glass enabled the glass to be provided with both NIR absorption and IR reflection. An absorbing SnO₂ film was doped with about 30% and the reflecting film with 2 to 3% of antimony oxide. The production method was the same as in the patent mentioned above, i.e. spray pyrolysis. The production times of the reflecting film were in the order of 8 seconds.

In the above patents flat glass was coated after the production process. U.S. Pat. No. 3,652,246 disclosed a method for coating flat glass by spray pyrolysis during the production process. The patent does not discuss the manufacturing of low-e glass, but dyeing of glass by means of spray pyrolysis. The patent mentions that tin and tin oxide residues remaining on the glass surface from a float process enhance the adhesion of metal oxide films to the glass surface and thereby create products of better durability.

U.S. Pat. No. 3,850,679 discloses a method in which hot glass is coated with CVD in such a way that a gas mixture on the trailing surface of the CVD nozzle has a Reynolds number of at least 2500. In the specification Sopko refers to a Reynolds figure of at least 5000, which according to him allows a rapid deposition to be achieved. The deposition rate is not, however, identified in greater detail.

U.S. Pat. No. 4,187,336 discloses a glass structure that attenuates the drawback of low-e coatings, i.e. interference colours. According to the patent, the generally applied low-e coating thickness rates of 0.1-0.75 microns cause an aesthetic drawback, which is not approved in building glass. In thicker coatings interference colours do not appear, but such coatings are expensive to manufacture, they cause ‘a veil’ in the glass and are easily cracked. In the patented method this is prevented by depositing a film between the glass and the tin oxide layer, the refraction index of the film being the average of the glass and the tin oxide (i.e. about 1.74) and its thickness about 70 nm. According to the patent the film is deposited using CVD at a glass temperature of 450-500° C. The deposition rate of the film is not mentioned.

U.S. Pat. No. 4,584,208 discloses a method for using powdery starting materials for producing low-e coatings. The starting materials used in this patent are fine ground hexahalostannates [Y₂(SnHal₆)ₙ], where halogen Hal contains both chlorine and fluorine. The first claim states that a finely ground solid substance evolves tin-containing vapour at the temperature of the glass. The glass temperature is 400 to 750° C. In the method of the invention the powdery starting materials react on the surface of the glass and form the coating.

Coatings produced during processing of the glass, such as glass hardening, require a coating process speed that is not achievable by prior art methods. Publication “Chemical Vapour Deposition of Tin Oxide Thin Films” (Antonius Maria Bernardus van Mol, Eindhoven; technische Universiteit Eindhoven, 2003, ISBN 90-386-2715-7) discloses the deposition rates of a tin oxide film, which is essential in low-e coatings, at different temperatures. For example, in connection with a hardening process the temperature is 600 to 650° C. and the deposition rates, depending on the starting material, are as shown in Table I.

TABLE I
Deposition rates, according to source “Chemical Vapour Deposition of
Tinoxide Thin Films”, for depositing a tin oxide film of different starting
materials onto glass the temperature of which is about 600° C.

| Starting materials | Deposition rate, nm/s |
|---|---|
| SnCl₂ + O₂ | 3 |
| SnCI₄ + O₂ | 4 |
| SnC1₄ + H₂O | 10-25 |
| Sn(CH₃)₄ | 1-10 |
| SnCl₂(CH₃) + O₂/H₂O | 7 |

The reaction of tin dichloride SnCl₂ with oxygen that yields tin oxide is a first order reaction. The deposition most probably takes place as chemisorption of the tin dichloride onto the surface of the growing tin oxide grain.

When tin tetrachloride SnCl₄ reacts with oxygen and produces tin oxide, the deposition rate is fairly low and therefore water vapour is generally used together with the tin tetrachloride. Wartenberg (Wartenberg, E. W., Ackermann, P. W., Glastech. Ber., 1988, 61, 256) has stated that the reaction of water vapour with glass surface is extremely relevant as regards the deposition rate, and deposition is assumed to take place through reactions between Si—OH groups formed on the surface of the glass.

The {Sn(CH₃)₄} deposition of tetramethyl tin, TMT, into tin oxide in a CVD process is a complex process and the literature of the art presents different interpretations based on research carried out in different circumstances. The most central interpretation from the point of view of the present invention relates to the study of reactions that take place in a gas phase. An article published in 1990 (Aleksandrov, Y. A., Baryshnikov, Y. V., Zakharov, L L, Lazareva, T. I., Kinetika i Kataliz, 1990, 31, 727) discloses that a factor restricting the deposition rate in the CVD process is the detachment of the first methyl group from TMT and that the process contains the following reactions and intermediary products:

(CH₃)₄Sn→(CH₃)₃Sn+CH₃

CH₃+O→H₂CO+OH

(CH₃)₃Sn+O₂→(CH₃)₂SnO+CH₃O

CH₃O+(CH₃)₄Sn→(CH₃)₂SnOCH₃+CH₃

OH+(CH₃)₄Sn→(CH₃)₃SnOH+CH₃

(CH₃)₃SnOH→CH₄+(CH₃)₂SnO

(CH₃)₂SnO→2CH₃+SnO

OH→terminates onto the walls, for example.

On the surface of a substrate the intermediary products, such as SnO, are quickly oxidised into SnO₂.

In their research, Borman and Gordon also came to the conclusion that gas phase reactions are a factor restricting the CVD deposition rate (Bonnan, C. G., Gordon, R. G., 1. Electrochem Soc., 1989, 136, 3820). The results they obtained have been used for creating a kinetic model (Zawadzki, A. G., Giunta, C. J., Gordon, R. G., 1. Phys. Chern., 1992, 96(13), 5364). Chemical reactions (restricting the growth rate) that take place in the gas phase create intermediate reaction products that diffuse onto the surface of the substrate, where they become absorbed and then oxidized.

The effect of the starting agent of the tin oxide on the structure and properties of the tin oxide layer is difficult to analyse, because the effect of other variables may conceal that of the starting agent. If the starting agent contains chlorine, the produced tin oxide will probably also contain chlorine. If the chlorine replaces an oxygen atom in the structure, the number of free charge carriers created in the structure increases, thereby reducing the electrical resistance of the tin oxide. If the chlorine does not replace oxygen, but is located elsewhere in the crystal structure, it will act as an electron trap and thereby electrical resistance increases. On the other hand, if chlorine reacts with the glass matrix, sodium chloride may appear at the grain boundaries of the tin oxide crystals. Which one of the above effects will be the most significant one depends on the glass matrix and the other deposition parameters. Chlorine may be prevented from binding to the structure by using hydrogen as the carrier gas for the tin vapour that contains chlorine, whereby the chlorine reacts to produce hydrogen chloride and exits from the reaction area in the form of gas.

The electrical conductivity of the tin oxide film and the extent to which it reflects infrared radiation are mutually proportional. The electrical conductivity of the tin oxide film increases as the thickness of the film increases. Increasing the thickness of the film usually means a longer deposit time. In that case the tin oxide grains in the film grow bigger, which reduces the number of grain boundaries, thereby decreasing dispersion at grain boundaries and increasing mobility.

When low-e films are produced with the CVD method, the temperature of the substrate has a significant effect on the electrical conductivity of the deposited film. According to Van Molin, maximum conductivity is achieved when the temperature of the substrate is 450° C. and pure tin oxide is deposited. As to doped tin oxides, they do not show a corresponding maximum, but conductivity increases as temperature increases. However, Van Mol does not provide results for temperatures exceeding 500° C.

According to van Mol the reason for the improved conductivity is that due to the higher temperature, the grains are bigger and their crystallinity is better, which lead to a greater concentration of charge carriers and thereby to better electrical conductivity.

The table below shows prior art starting materials and production methods for preparing a low-e coating.

TABLE I
Prior art production of low-e coatings

| Source | Manufacturing method | Recipe |
|---|---|---|
| U.S. Pat. No. 2,564,708 | Spray pyrolysis, substrate | 100 g SnC₄ 5H₂0, 4 g SbCl₃, 1 g |
| (Mochel) | temperature about 1000 K | ZnCl₂, 50 cc H₂O and 10 cc HCl |
| U.S. Pat. No. 2,566,346 | Spray pyrolysis, substrate | 170 cc SnCl₄ |
| (Lytle & Junge) | temperature about 890 K | 1000 cc methanol |
| | | 6 g NH₄HF₂ |
| | | or |
| | | 4 g SnF2 |
| | | 4 g methanol |
| | | 25 g water |
| U.S. Pat. No. 2,651,585 | Spray pyrolysis, substrate | 90 wt % SnCl₄ 5H₂O |
| (Lytle & Junge) | temperature about 940 K | 10 wt % aqueous formaldehyde |
| | | solution containing 40% of |
| | | formaldehyde |
| | | or |
| | | 1000 cc SnCl₄ |
| | | 5000 cc methanol |
| | | 100 g NH₄HF₂ |
| U.S. Pat. No. 3,331,702 | CVD, substrate | 99 wt % SnCl₄ 5H₂O |
| (Dates & Davis) | temperature 820 K | 1 wt % SbCl₃ |
| | | mixed prior to vaporization |
| U.S. Pat. No. 3,473,944 | CVD, substrate | 99-20 wt % SnCl₄ 5H₂O |
| (Dates & Davis) | temperature not mentioned | 1-80 wt % SbCl₃ |
| | | mixed prior to vaporization |
| U.S. Pat. No. 4,146,657 | CVD, substrate | Vapours are produced by bubbling |
| (Gordon) | temperature 770 K | nitrogen through Sn(CH₃)₄ and |
| U.S. Pat. No. 4,265,974 | | SnCF₃(CH₃)₃ bubblers and by |
| (Gordon) | | mixing oxygen with the vapour |
| | | mixture so that the resulting gas |
| | | mixture contains |
| | | 1% Sn(CH₃)₄ |
| | | 0.02% SnCF₃(CH₃)₃ |
| | | 10% N₂ |
| | | the rest: O₂ |
| U.S. Pat. No. 4,294,193 | CVD, substrate | The film consists of two layers, |
| (Gordon) | temperature about 570 K | the recipe for the first layer: |
| | | 0.7 mol-% 1,1,2,2- |
| | | tetramethyldisilane |
| | | 1.4 mol-% Sn(CH₃)₄ |
| | | 2.0 mol-% CF₃Br (Freon13BI) |
| | | the rest: dry air |
| | | the recipe for the second layer |
| | | 1.6 mol-% Sn(CH₃)₄ |
| | | 3.0′ mol-% CF₃Br (Freon13BI) |
| | | the rest: dry air |
| U.S. Pat. No. 4,500,567 | CVD, substrate | C₄H₉SnCl₃, bubbler temperature 40-90° C., |
| (Kato, Kawahara & | temperature 790 K | nitrogen through bubbler 30 |
| Hyohdou) | | SLM; |
| | | the mixing gas: |
| | | Cl—CHF₂, or |
| | | F—CHF₂, or |
| | | CH₃—CHF₂ |
| U.S. Pat. No. 4,524,718 | CVD, substrate | The raw materials are fed from two |
| (Gordon) | temperature not mentioned. | different feed ends, and they react |
| | | on the surface of the glass, whereby |
| | | a deposition rate of about 200 nm/s |
| | | is obtained. |
| | | Mixture 1: |
| | | 0.5-1 mol-% SnC14 |
| | | carrier gas (nitrogen or air); about |
| | | 50% of the total carrier gas amount |
| | | Mixture 2: |
| | | 10-20 mol-% H2O |
| | | 0.03-0.06 mol-% HF |
| | | 0-30 mol-% CH₃OH |
| | | carrier gas (nitrogen or air): about |
| | | 50% of the total carrier gas amount |
| U.S. Pat. No. 4,584,208 | Reaction of powdery | Ammoniumhexahalostannate |
| (Hargreaves) | substances with the | prepared by dissolving 100 rnl |
| | surface, glass surface | distilled water with 50 g of SnC1₄ |
| | temperature 920 K | 5H₂O and 5.3 g of NH₄F. The |
| | | solution was dried in an exiccator |
| | | (vacuum), until white, crystalline |
| | | powder was produced. To this was |
| | | added 2% of amorphous silica and |
| | | the mixture was ground to a grain |
| | | size of <100 mm. The powder was |
| | | mixed into a carrier gas (fluidised |
| | | bed) and taken to the surface of the |
| | | glass. |
| U.S. Pat. No. 4,721,632 | Spray pyrolysis, glass | The coating consists of two parts, |
| (Brown) | temperature 810-950 K | one of which ‘fluorinates’ the glass |
| | | surface and the other brings the tin |
| | | oxide. The raw material composition |
| | | of the first coating: 5-10 wt % |
| | | NH₄F |
| | | 90-95 wt % of a mixture of |
| | | methanol and water containing equal |
| | | amounts of methanol and water in |
| | | percent by weight. The raw material |
| | | composition of the second coating: |
| | | 53.8 wt % C₄H₉SnCl₃ |
| | | 1.4 wt % NH₄F |
| | | 1.4 wt % H₂O |
| | | 43.4 wt % methanol |
| U.S. Pat. No. 4,900,634 | Spray pyrolysis, glass | 1000 ml water |
| (Terneu & van Cauter) | temperature about 820 K | 900 g SnCl₃ |
| | | 65 g NH₄HF₂ |
| | | 40 g SbCl₃ |
| | | (emissivity 0.18) |
| | | or |
| | | 1000 ml water |
| | | 900 g SnCl₃ |
| | | 65 g NH₄HF₂ |
| | | 31 ml HNO₃ |
| | | emissivity 0.16 |
| U.S. Pat. No. 4,990,286 | APCVD, substrate | 500 sccm He (CH₃CH₂)₂Zn through |
| (Gordon) | temperature about 720 K | bubbler |
| | | (25° C.), combining 5.5 SLM with the |
| | | He flow. Second flow. |
| U.S. Pat. No. 5,830,530 (Jones) | MOCVD, substrate | Tetratertiary butoxy tin in |
| | temperature 520-670 K | {Sn(OBu^{t})₄}bubbler (80° C.), through |
| | | which a nitrogen flow of 75 sccm is |
| | | taken, adding 100 sccm into the |
| | | nitrogen flow and leading to the |
| | | surface of the glass. |
| U.S. Pat. No. 6,797,388 | CVD, substrate | ATC (SbCl₃) is diluted into MBTC |
| | temperature about 930 K | (C₄H₉SnCl₃) such that the proportion |
| | | of ATC in the solution is 7 wt %; the |
| | | solution is heated to 175° C.. Bubbled |
| | | by means of nitrogen, adding |
| | | dilution nitrogen so that the |
| | | proportion of reactive agents in the |
| | | gas flow is about 0.8-1 mol-%. The |
| | | vapour is directed to the surface of |
| | | the glass, the temperature of the |
| | | glass pyrolising reactive agents. |
| | | Gaseous reaction products (such as |
| | | hydrochloric acid/chlorine) are taken |
| | | to a conventional thermal oxidizer |
| | | and then discharged through a |
| | | conventional filter. |
| Elangovan & | Spray pyrolysis | 11 g of SnCl₂ 5H₂O was dissolved |
| Ramamurthi, | | into 5 ml of concentrated HCl at |
| Journal of | | 90° C., mixing time 10 min. The |
| Optoelectronics and | | solution was further dissolved into |
| Advanced Materials, | | methanol. NH₄F was dissolved |
| Vol5 | | (twice) into distilled water and |
| No. 1, March 2003, PP. | | added into the solution. |
| 45-54 | | |

The prior art methods cannot be used for producing glass coatings at the speed glass proceeds for example in glass processing, such as on a glass hardening line.

### SUMMARY OF THE INVENTION

It is an object of the invention to eliminate the problems of the prior art and to provide a new method for coating glass at the production speed thereof. The method of the invention allows glass to be coated while it moves on the glass production or processing line. The glass typically has a velocity of 0.4 to 1 m/s and a temperature of 500 to 750° C. The object of the invention is achieved by a method according to the preamble of claim 1, which is characterized in that to deposit a coating, some of the coating material is delivered into the coating in the form of solid particles whose composition is substantially the same as the composition of the coating to be deposited and whose diameter is less than 200 nm. The object of the invention is further achieved by an apparatus according to the characterizing part of claim 6, which is characterized in that the apparatus comprises means for producing particles of a diameter of less than 200 nm and for conveying the particles into a gas mixture to be used in CVD deposition, the mixture consisting of at least one gas.

The preferred embodiments of the invention are disclosed in the dependent claims.

The invention is based on the idea that the raw materials used for coating a glass product react to form single or multiple-component oxides primarily in a gas phase prior to a contact with the glass surface, and therefore the slowness of reactions taking place on the glass surface and/or the slowness of non-oxidizing reactions taking place in the gas phase do not restrict the deposition rate.

In this context ‘primarily’ means that some of the oxidizing reactions of the coating agent only take place on the glass surface, these reactions causing a chemisorption on the surface of the glass.

According to the invention the coating to be deposited onto the glass surface thus consists at least partly of particles whose composition is substantially the same as the composition of the coating and which allow a significantly higher effective deposition rate of the coating to be achieved than in a convention CVD process.

The coating method of the invention may be implemented using the CVD method as a starting point.

With the method disclosed here, the coating of glass may be integrated into the glass processing line, which significantly improves the cost-effectiveness of the production of coated and processed glass.

Representative examples are disclosed below with reference to the accompanying drawings.

### BRIEF DESCRIPTION OF THE DRAWINGS

FIG. 1 illustrates a coating according to the method, the coating on the glass being tin oxide doped with fluorine.

FIG. 2 illustrates the production of the coating according to the invention with the CVD coating method as a starting point. The coating takes place at the heating part of the glass hardening line.

FIG. 3 illustrates a modified CVD burner head and a process for producing a coating according to the invention.

FIG. 4 illustrates the production of the coating according to the method with a spray pyrolysis coating method used as a starting point. The coating apparatus is on the glass production line, between a tin bath and a cooling furnace.

FIG. 5 illustrates a coating according to the method, the coating having material deposited at grain boundaries of the coating grains, the material having a better electrical conductivity than the grains.

FIG. 6 illustrates the production of the coating according to the method using the flame spray method disclosed in Finnish patent F198832 as a starting point. The coating apparatus is at the output of the heating part of the hardening line. According to the method, material is deposited to the grain boundaries of the grains in the coating, the material having a better electrical conductivity than the grains.

### A DETAILED DISCLOSURE OF THE INVENTION

The present invention relates to a method for coating glass, the basic idea of the method being than at least some of the coating is brought onto the glass surface in the form of small particles, whereby reactions taking place on the glass surface do not constitute a factor restricting the coating speed of the glass. The method may be applied to various glass materials, such as soda glass, borosilicate glass, crystal and semi-crystal glass and to quartz glass. The method is also applicable to glazed products, such as glazed ceramic products, of which glazed ceramic tiles are one example.

The glass is coated using a deposition method of the invention, in which some of the material deposits onto the surface of fine particles created in a gas phase or separately delivered therein. The fine particles may be produced using a CVD, spray pyrolysis or a flame spray method, or some other method.

In this context the term ‘fine particle’ is used to refer to a particle having a diameter smaller than a quarter of the wavelength of visible light, i.e. typically less than 200 nm.

The coating may be a low-e coating needed in energy saving glass, for example, the material of the coating being typically tin oxide doped with fluorine and/or antimony. Typically this kind of coating should have a thickness of 200 to 600 nm, preferably about 400 nm. In the CVD process the deposition rate of this kind of coating is in the order of 20 nm/s, the deposition time of the coating thus being about 20 seconds. Since in a glass hardening process, for example, the surface of the glass stays at the coating point only for less than a second, the CVD deposition method as such is too slow.

According to the invention, doped tin oxide particles having a diameter of a median of 30 nm are created in the process or delivered therein. These particles are allowed to travel within the gas flow, whereby doped tin oxide is deposited onto their surfaces at an approximately the same rate as onto the surface of glass. Hence during one second the surface of the particles is deposited with a layer of about 20 nm, i.e. the particles grow into particles of a diameter of about 70 nm. Due to the Brownian movement, thermoforesis and/or electrical forces, the particles are driven to the surface of the glass. Chemical reactions taking place on the surface of the glass and the particles attach the particles chemically to the glass surface, thus producing a uniform coating. The effective deposition rate, i.e. the rate of deposition onto the glass surface, is in the order of 300 nm/s for a coating of this kind.

According to empirical knowledge on low-e coatings, a film that conducts electricity well has a low emissivity. Electrical conductivity in a film depends not only on the density of the charge carriers but also on their mobility μ, which may be determined as a proportionality factor between an accelerating electric field E and charge carrier speed v so that v=μE.

The mobility of the charge carrier is determined by the dispersion parameters of the intermediate agent; there are many parameters, and the Bolzmann transport theory, for example, may be applied to them. As total dispersion increases, mobility decreases. An electron moving in an ideal, periodic gate does not experience dispersion and therefore mobility increases to a very high degree.

Supraconductive materials in a suitably low temperature resemble this type of environment. The conductivity of film depends on the product obtained by multiplying the number of charge carriers by mobility. In other words, maximizing the electrical conductivity of a low-e film by acting on mobility alone does not necessarily reduce emissivity.

A thin film is not necessarily homogenous, but may also contain large amounts of different kinds of errors in crystal. A local crystal structure may also change from one crystal type to another. At grain boundaries the electrical properties of the film are significantly different than inside the grain. Transport of electricity across grain boundaries depends on various factors and generally results from the termination of the periodicity of a crystal grating and from the ways in which the points of adhesion at a grain edge are filled with foreign atoms or molecules. How the points of adhesion are filled determines whether the surface of the grain becomes negatively or positively charged, or whether it remains electrically neutral. An ideal filling agent is hydrogen. The surface of a chemically clean silica oxide, for example, that may be obtained by cleaving a clean silica crystal in a vacuum, remains positively charged until the surface is contaminated by foreign atoms and the electrons in them neutralize it. The treatment of the surface of silica oxide to make it advantageous is commonly used in MOSFET technology in connection with the manufacture of integrated circuits.

In connection with thin films and grain boundaries the restricted space for a charge carrier is easily less than 300 Å. In that case it should be noted that the physical dimensions of the structure are less than the extent of a quantum mechanical wave function of a free electron and therefore the electron no longer corresponds to a classically localised particle. The wave function, or the probability amplitude of a particle, in a way represents the most probable effective area of the energy contained in the electron. This has a major significance on the electrochemical behaviour of matter and in fact therefore film properties often must be addressed through concepts used in quantum mechanics. Consequently, the probability of an imaginary electron tunneling at the grain boundary from one grain to another may be significant. Similarly, chemical particles formed through flame reactions, for example, cannot be considered as classical particles before their “size” exceeds at least the length required by the wave function of a free electron. Hence a grain having a size of less than 30 nm does not contain a “free” charge carrier in the proper sense of the word and therefore its “surface”, for example, may behave differently than that of a macroscopically corresponding particle, because the free dimension of a classical electron would extend across the entire structure.

The electrical field of a surface is usually described as the bending of the energy bands in the material. If the surface has a positive charge, it lacks electrons (a discharge zone) and the bands are described as being bent upwards. Depending on how deep into the grain the bending extends in relation to the grain size, the area of free charge carriers becomes narrower and the electrical resistance of the grain increases. Since the emissivity of a film depends on the number of free charge carriers, in low-e coatings it is important to act on the composition of the grain boundaries so that the total charge carrier density remains high. This may be achieved for example by doping the surface with a suitable doping agent for returning charge neutrality, or at least for adjusting the surface charge so that it is advantageous in relation to the functioning of the film. The surface of the grain may be provided with suitable metals that adhere chemically to the grain. In the case of tin oxide this kind of metal may be silver, for example.

### EXAMPLES

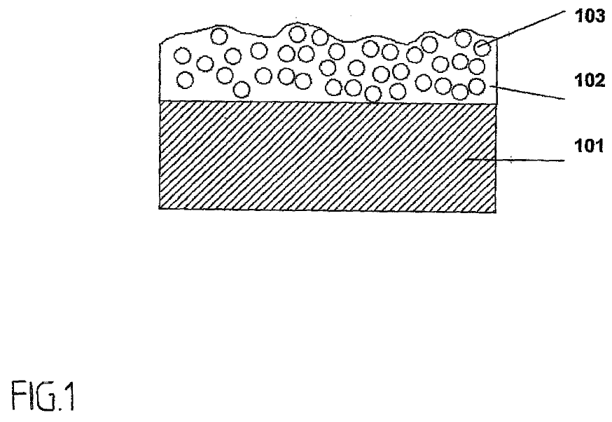

In the following the invention will be described in greater detail with reference to examples and FIGS. 1 to 6.

### Example 1

### Low-e Coating Produced by Means of a Modified CVD Method

With reference to FIG. 1, a coating is deposited onto the surface of glass 101, the coating consisting of a coating matrix 102 and particles 103, which are substantially of the same material as the coating matrix 102. In the low-e coating of the example both materials consist of tin oxide doped with fluorine.

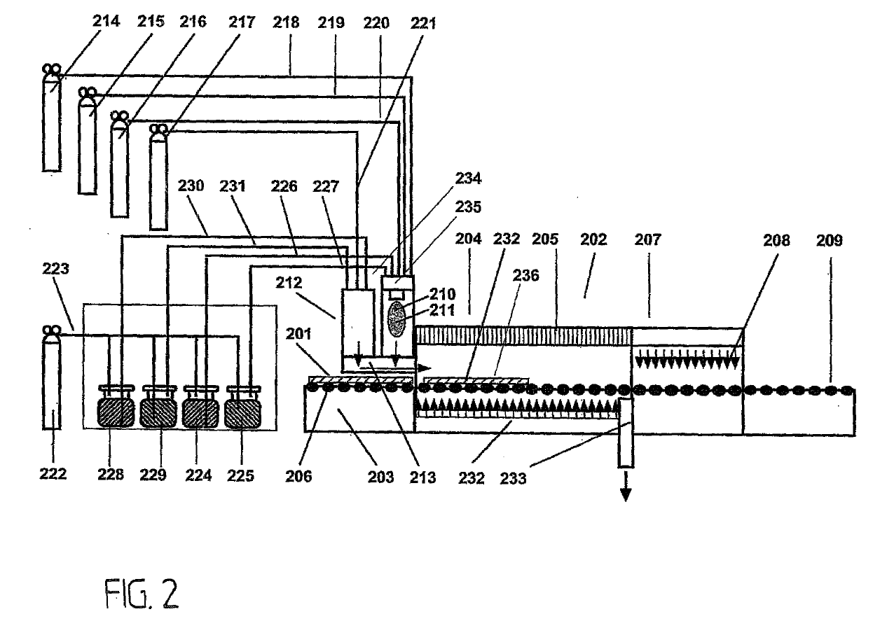

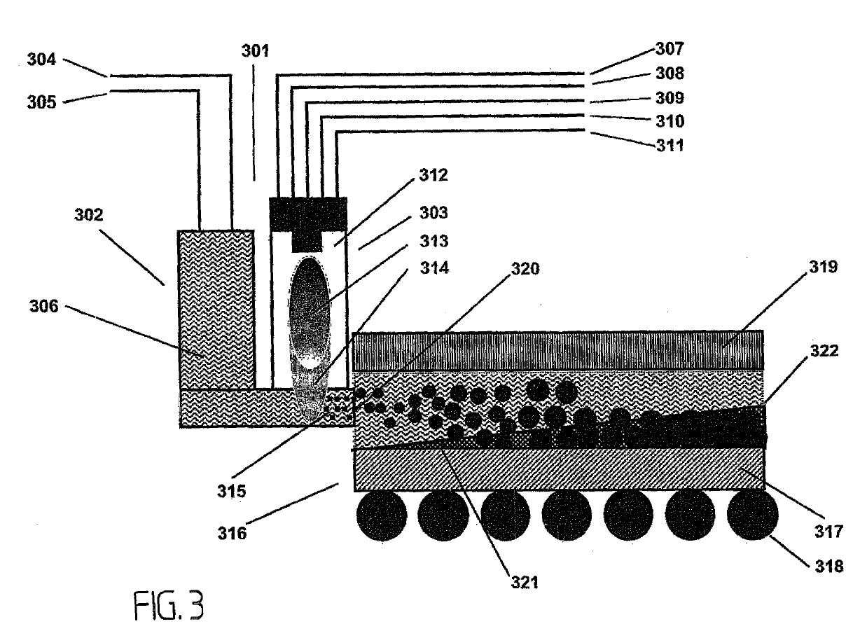

With reference to FIG. 2, the coating of FIG. 1 is produced onto the surface of glass 201 in a glass hardening apparatus 202. A glass plate 201 is first placed into a loading unit 203, from where the glass plate 201 proceeds on transport rolls 206 to a heating furnace 204. In the furnace 204 the glass plate 201 is heated by means of radiant heaters 205. After the heating the glass moves quickly into a cooling chamber 207, where the glass is cooled by means of air jets 208. The glass then proceeds to discharge rolls 209. The surface of the glass 201 is provided with a low-e film 236 produced by means of a modified CVD deposition apparatus 234. The deposition apparatus 234 consists of a CVD feed chamber 212 and a particle generator 235. In this example the particle generator 235 is a liquid flame spray device according to FI Patent 98832, in which a hydrogen-oxygen flame 210 is used for creating particles 211 of a size of 10 to 110 nm. The mechanism that produces the particles and the method of the invention will be disclosed in greater detail with reference to FIG. 3 below.

The CVD feed chamber 212 and the particle generator 235 are fed with liquid, vaporous or gaseous raw materials. From a gas container 214, hydrogen is supplied on feed line 218 to serve as the fuel gas for creating a flame in the particle generator 235. From a gas container 215, oxygen is supplied on feed line 219 to serve as flame-forming gas in the particle generator 235. From a gas container 216, nitrogen is supplied on feed line 220 to regulate the flame of the particle generator 235. For the sake of clarity, flow controllers and meters, shut-off and no-return valves, filters, and other similar feed line components obvious to a person skilled in the art have not been indicated.

From a gas container 222, nitrogen is supplied into a bottle 224, whereby the bottle 224 is pressurized. The bottle 224 contains a liquid mixture prepared by dissolving 22 g of hydrous tin chloride, SnCl₃.5H₂O, into 10 ml of concentrated hydrochloric acid. This mixture is further dissolved into 1200 ml of methanol. After that, 20 ml of distilled water is added into the mixture and 2.8 g of ammonium fluoride, NH₄F, is dissolved therein. The solution is conveyed from the bottle at a volume flow of 50 ml/min. For the sake of clarity, flow controllers and meters, shut-off and no-return valves, filters, and other similar line 20 components obvious to a person skilled in the art have not been indicated. Alternatively, it is possible to use a suitable mixture of tin and fluorine compounds, which is then vaporized in a bubbler 225.

From the gas container 222, nitrogen is conveyed to a bubbler 228, whereby tin tetrachloride SnCl₄ in the bubbler evaporates and is further conveyed on a gas pipe 230 to the CVD feed chamber 212. Alternatively, the tin compound may be atomized into the CVD feed chamber 212 by pressurizing the feed bottle 229. The feed chamber 212 is also fed with a fluorine compound ClCHF₃ from a gas container 217 along a gas pipe 221. Again, flow controllers and meters, shut-off and no-return valves, filters, and other similar line components obvious to a person skilled in the art have not been indicated. The ratio of the tin tetrachloride to the fluorine compound is adjusted such that the composition of a film produced from the compounds by means of CVD deposition is substantially the same as the composition of particles created in the particle generator 235. The volume flow of the fluorine compound may be regulated in a simple manner by means of a mass flow regulator, for example. The mass flow of the tin tetrachloride may be calculated using the following formula:

$${Q}_{i} = \frac{{p}_{i} p}{( p - {p}_{i} ) {RT}_{0}} {η}_{i} V$$

Where Qᵢ is the mass flow (mol/min), V is the nitrogen flow into the bubbler (I/min), p is air pressure and pᵢ is partial pressure of the tin tetrachloride, R is a general gas constant, Tₒ is the absolute temperature and ηᵢ is the vaporization efficiency.

In the case used as an example, the nitrogen flow through the bubbler was 1300 ml/min, the temperature of the bubbler 50 C and the fluorine gas flow 20 ml/min.

The created particles 211 and the gas mixture mixed in the CVD feed chamber 212 are further supplied through a combining chamber 213 into a hardening furnace 204.

With reference to FIG. 3, raw materials are fed through feed conduits 304 and 305 into the CVD chamber 302 of the apparatus 301 and the raw materials mix to form a gas mixture 306. Correspondingly, raw materials and fuel gases are fed from feed conduits 307, 308, 309, 310 and 311 into a particle generator 303 belonging to the apparatus 301. Liquid raw materials are atomized in an atomizer 312 and all the raw materials are mixed and they travel to a flame 313, where they react and form fine particles 314, whose diameter is typically between 10 and 100 nm. The diameter of the particles is primarily determined by the particle content in the immediate vicinity of the flame, and in the example under discussion the particle concentration is such that the median diameter of the particles is 30 nm.

The created particles 314 further mix with the gas mixture 306 in a mixing pipe 315 and travel into a furnace 316 of the hardening line. In the furnace 316 the glass 317 moving on transport rolls 318 is heated by means of radiant heaters 319. The temperature of the glass is typically raised to 600 to 650 C. At this temperature tin tetrachloride SnC₄ does not react to form particles, but CVD deposition on the surface of the particles 320 and the glass 317 takes place in the hardening furnace 316. Since the sum of the surface of the particles is multifold compared to the surface of the glass, increase in the amount of solid matter takes place mainly on the surface of the particles 320. The particles further gather onto the surface of the glass due to the Brownian movement, gravitation, thermoforesis and electrical forces, whereby the joint effect of the particle accumulation and the CVD deposition allow a uniform coating 322 to be provided onto the surface of the glass at a deposition rate which is substantially greater than the rate of CVD onto glass surface.

### Example 2

### Coating Produced by Means of a Modified Spray Pyrolysis Method

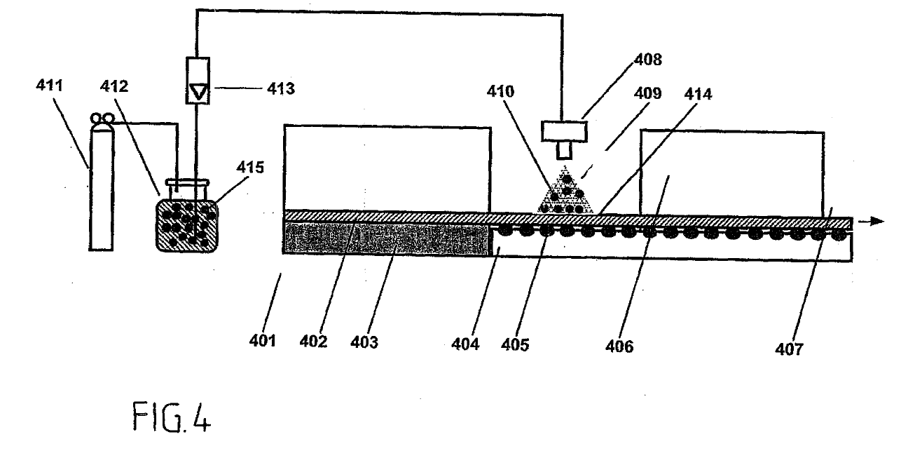

With reference to FIG. 4, a glass sheet 402 travelling on a glass production line (“float line”) 401 is coated in a space 404 left between a tin bath 403 and a cooling furnace 406, the temperature of the glass in the space being 550 to 650° C. Coated glass is obtained from the discharge end 407 of the production line. According to the invention, the coating is carried out using a spray pyrolysis nozzle 408, in which the raw material 412 is sprayed to form a mist 409 of small droplets and guided onto the surface of the glass sheet 402, where heat causes the raw material to react with the glass, whereby a coating 414 is formed.

The method of the invention differs from the prior art spray pyrolysis method in that the raw material 412 contains particles 415 of a diameter of 200 nm mixed therein. The particles 415 are produced by a method disclosed in FI Patent 98832, for example a liquid flame spray method, laser ablation, wet methods, laminar flamer burner, tube reactor, or some other prior art method for producing nanomaterial. The composition of the particles is substantially the same as the composition of a film produced in a spray pyrolysis method. The particles 415 travel within the liquid flow into the mist 409, 410 and further into the coating 414. The particles form a significant portion of the coating mass and therefore the deposition rate of the coating to be produced is significantly greater than the deposition rate of a spray pyrolysis coating alone.

### Example 3

### Low-e Coating Produced by Improving the Electrical Conductivity of Grain Boundaries

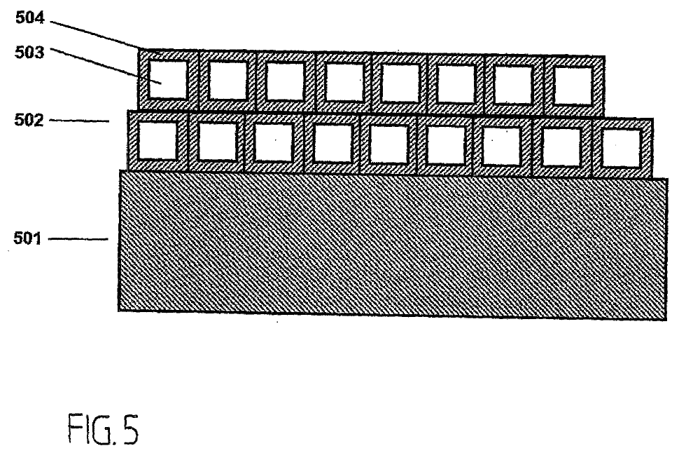

With reference to FIG. 5, the method of the invention may be used for providing the surface of glass 501 with a coating 502 consisting of a basic material 503 made up of nano-sized particles and a material 504 deposited around basic material particles 503 and having a greater electrical conductivity than the basic material 503. This allows dispersion at the grain boundaries to be reduced and the electrical conductivity of the coating to be increased. A thin low-e coating thus functions in the same way as a thicker coating deposited of the basic material 503, i.e. the effective deposition rate of the coating is increased.

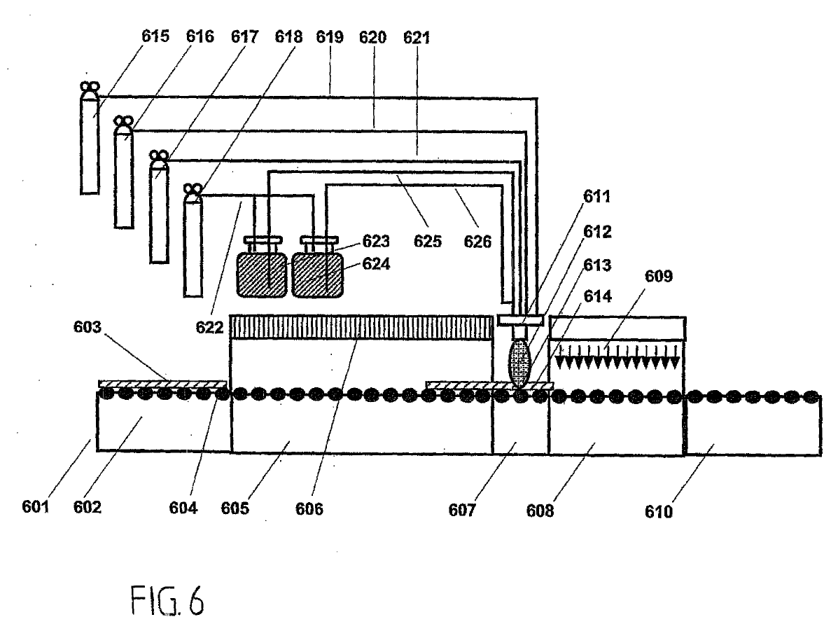

The coating shown in FIG. 5 may be produced in connection with glass hardening, for example, by means of an apparatus shown in FIG. 6.

With reference to FIG. 6, the coating shown in FIG. 5 is produced onto the surface of glass 603 in a glass hardening apparatus 601. A glass plate 603 is first placed into a loading unit 602, from where transport rolls 604 move the glass plate 603 into a heating furnace 605. In the furnace 605 the glass plate 603 is heated by means of radiant heaters 606 to a temperature of 600 to 700° C. After the heating the glass moves quickly into a cooling chamber 608, where the glass is cooled by means of air jets 609. From there the glass moves to a discharge section 610.

Between the heating unit 605 and the cooling unit 608 there remains a section 607 into which a liquid flame spray apparatus 611 is placed. A liquid flame spray method is disclosed in Finnish Patent F198832. In the liquid flame spray 611 the raw materials react in the flame 613 and form nanoparticles 613, which further deposit onto the surface of the glass 603 and form a coating 614.

Nanoparticles are formed in the liquid flame spray when the raw materials vaporize, possibly react with oxygen and form metal oxides, concentrate into small particles (form nuclei) and further grow into particles of 10 to 100 nm due to condensation, the size depending on the concentration of metal in the flame and in the immediate vicinity thereof. Substances that react easily with oxygen, such as tin, are easily oxidized and form particles at a higher temperature than metals that oxidize weakly, such as noble metals. With this method it is possible to produce in a single process particles having a metal oxide core surrounded by a noble metal surface.

In the present invention this phenomenon is utilized for producing a low-e coating. From a gas container 615 and 616 hydrogen and oxygen gases are supplied along feed pipes 619 and 620 to the liquid flame spray 611 to produce a flame. From a gas container 617 nitrogen needed for regulating the flame 612 is supplied in feed conduit 621. For the sake of clarity, flow controllers and meters, shut-off and no-return valves, filters, and other similar feed line components obvious to a person skilled in the art have not been indicated. From a gas container 618 nitrogen is supplied to raw material containers 623 and 624. The raw material container 623 contains the solution mention in example 1 for producing SnO2:F particles. The raw material container 624 contains silver nitrate, AgNO3, dissolved into methanol.

The raw materials are taken close to the liquid flame spray 611 along feed conduits 625 and 626, and the feeds are combined before the liquid flame spray 611.

In the flame the raw materials react and thereby tin oxidizes, the tin oxide is doped with fluorine and the oxide particles form nuclei and grow as a result of condensation. In a later phase of the flame, silver is condensed onto the surface of the particles either in the form of particles or as a film. Some of the silver and some of the tin oxide may also be deposited directly onto the surface of the glass 603. The surface of the glass becomes deposited with a coating 614 that is substantially like the coating in FIG. 5, i.e. the boundary surfaces of the particles are provided with at least patches or particles of silver, which enhances electrical conductivity between particles. This enables to obtain a film that is more conductive than the basic material, i.e. an effectively greater film deposition rate is achieved.

A person skilled in the art will find it obvious that there are also other ways to produce the structures disclosed in the examples, and that an essential aspect in the invention is that the film deposition rate is increased by delivering some of the material in the form of solid particles. Further, the effective growth rate of low-e films may be increased by improving electrical conductivity at the boundary surfaces of the grains in the film.

1. A method for coating glass by means of a CVD method, in which to deposit a coating, some of the coating material is delivered into the coating in the form of solid particles, whose composition is substantially the same as the composition of the coating to be deposited and whose diameter is less than 200 nm, wherein the coating to be deposited reflects infrared radiation in such a way that the amount of the infrared radiation reflected exceeds 70% (a low-emissivity, or low-e, coating).

2. A method according to claim 1 for coating glass, wherein the method is used for producing a low-emissivity (low-e) film onto the glass surface in such a way that the composition of the core in the particles of a diameter of less than 200 nm is substantially the same as the composition of the low-emissivity film to be deposited and that the shell of the particles in question consists of a material whose electrical conductivity is greater than the electrical conductivity of the core of the particles.

3. A method according to claim 2, wherein the material of the low-emissivity film and the core of the particles is SnO2; SnO2:F; SnO2:Sb; SnO2:F:Sb; ZnO:F, or a combination of these, and the material of the particle shell is Ag, Au, Pt, Pd, or a combination of these.

4. A method according to claim 1, wherein the adhesion of the coating to the glass surface primarily takes place through chemisorption caused by the CVD deposition.

5. An apparatus for coating glass comprising means for producing particles of a diameter of less than 200 nm and for conveying the particles into a gas mixture to be used in CVD deposition, the mixture consisting of at least one gas, wherein the apparatus is arranged to be used in connection with a method according to claim 1.

6. (canceled)

7. (canceled)

8. An apparatus for coating glass comprising means for producing particles of a diameter of less than 200 nm and for conveying the particles into a gas mixture to be used in CVD deposition, the mixture consisting of at least one gas, wherein the apparatus is arranged to be used in connection with a method according to claim 2.

9. An apparatus for coating glass comprising means for producing particles of a diameter of less than 200 nm and for conveying the particles into a gas mixture to be used in CVD deposition, the mixture consisting of at least one gas, wherein the apparatus is arranged to be used in connection with a method according to claim 3.

10. An apparatus for coating glass comprising means for producing particles of a diameter of less than 200 nm and for conveying the particles into a gas mixture to be used in CVD deposition, the mixture consisting of at least one gas, wherein the apparatus is arranged to be used in connection with a method according to claim 4.
